(19) United States
(12) Patent Application Publication
(10) Pub. No.: US 2024/0145407 A1
(43) Pub. Date: May 2, 2024

(54) DEEP VIA WITH INTERNAL VOID FOR STRESS MITIGATION

(71) Applicant: INTERNATIONAL BUSINESS MACHINES CORPORATION, Armonk, NY (US)

(72) Inventors: Julien Frougier, Albany, NY (US); Ruilong Xie, Niskayuna, NY (US); Kangguo Cheng, Schenectady, NY (US)

(21) Appl. No.: 17/978,465

(22) Filed: Nov. 1, 2022

(51) Int. Cl. H01L 23/00

(52) U.S. Cl. CPC H01L 23/562

(57) ABSTRACT

A deep-via structure includes at least one via-interfacing layer. The deep-via structure also includes a via. The via is embedded within the at least one via-interfacing layer. The via includes a conductive material. The deep-via structure also includes a stress-relief void that is formed within the conductive material of the via.

### BACKGROUND

The present invention relates to microcircuitry connection, and more specifically, to deep vias.

Some circuitry chips (e.g., microprocessor chips, memory chips) include vias to electrically connect layers of those chips. Vias typically take the form of a trench that is etched and then filled with a conductive material. An electrical signal from the circuitry in one layer may travel through the via to the circuitry in a second layer.

Typical vias may be approximately 10 nm wide and span several layers of a chip. Some designs also include significantly larger vias. These significantly larger vias may, depending on the use case, sometimes be referred to as “deep vias” or, in some specific use cases, “through-silicon vias” or “through-chip vias.” Deep vias may be 10,000 nm (10 microns) or even 15,000 nm (15 microns) wide and span 100,000 nm (100 microns) of a chip. These larger vias may sometimes be used to connect a chip to another system component (e.g., to a ball-grid array) or to connect different areas of the same chip.

### SUMMARY

Some embodiments of the present disclosure can be illustrated as a deep-via structure. The deep-via structure comprises a via-interfacing layer. The deep-via structure also comprises a via that is embedded within the via-interfacing layer. The via comprises a conductive material. The deep-via structure also comprises a stress-relief void that is formed within the via.

Some embodiments of the present disclosure can also be illustrated as a microprocessor chip. The microprocessor chip comprises a first deep via structure and a second deep via structure. The first deep-via structure comprises a first via-interfacing layer and a first via that is embedded within the first via-interfacing layer. The first via comprises a conductive material. The first deep-via structure comprises a first stress-relief void that is formed within the first via. The second deep-via structure comprises a second via-interfacing layer. The second deep-via structure comprises a second via that is embedded within the second via-interfacing layer. The second via comprises a conductive material. The second deep-via structure also comprises a second stress-relief void that is formed within the second via.

### BRIEF DESCRIPTION OF THE DRAWINGS

FIG. 1 discloses a deep-via structure with a stress-relief void and a bi-layer dielectric.

FIG. 2 discloses a deep-via structure with a stress-relief void and a spacer element.

FIG. 3A discloses a first stage of forming a deep via with a stress-relief void in a bi-layer dielectric.

FIG. 3B discloses a second stage of forming a deep via with a stress-relief void in a bi-layer dielectric.

FIG. 3C discloses a third stage of forming a deep via with a stress-relief void with a stress-relief void in a bi-layer dielectric.

FIG. 3D discloses a fourth stage of forming a deep via with a stress-relief void in a bi-layer dielectric.

FIG. 3E discloses a fifth stage of forming a deep via with a stress-relief void in a bi-layer dielectric.

FIG. 3F discloses a sixth stage of forming a deep via with a stress-relief void in a bi-layer dielectric.

FIG. 3G discloses a seventh stage of forming a deep via with a stress-relief void in a bi-layer dielectric.

FIG. 3H discloses an eighth stage of forming a deep via with a stress-relief void in a bi-layer dielectric.

FIG. 3I discloses a ninth stage of forming a deep via with a stress-relief void in a bi-layer dielectric.

FIG. 3J discloses a tenth stage of forming a deep via with a stress-relief void in a bi-layer dielectric.

FIG. 3K discloses an eleventh stage of forming a deep via with a stress-relief void in a bi-layer dielectric.

FIG. 3L discloses a twelfth stage of forming a deep via with a stress-relief void in a bi-layer dielectric.

FIG. 4A discloses a first stage of forming a deep via with a stress-relief void and a spacer dielectric.

FIG. 4B discloses a second stage of forming a deep via with a stress-relief void and a spacer dielectric.

FIG. 4C discloses a third stage of forming a deep via with a stress-relief void and a spacer dielectric.

FIG. 4D discloses a fourth stage of forming a deep via with a stress-relief void and a spacer dielectric.

FIG. 4E discloses a fifth stage of forming a deep via with a stress-relief void and a spacer dielectric.

FIG. 4F discloses a sixth stage of forming a deep via with a stress-relief void and a spacer dielectric.

FIG. 4G discloses a seventh stage of forming a deep via with a stress-relief void and a spacer dielectric.

FIG. 4H discloses an eighth stage of forming a deep via with a stress-relief void and a spacer dielectric.

FIG. 4I discloses a ninth stage of forming a deep via with a stress-relief void and a spacer dielectric.

FIG. 4J discloses a tenth stage of forming a deep via with a stress-relief void and a spacer dielectric.

FIG. 4K discloses an eleventh stage of forming a deep via with a stress-relief void and a spacer dielectric.

FIG. 4L discloses a twelfth stage of forming a deep via with a stress-relief void and a spacer dielectric.

FIG. 5 discloses a process of forming a deep via with a stress-relief void.

### DETAILED DESCRIPTION

In microcircuitry, vias typically take the form of trenches filled with conductive material that primarily extends from and perpendicular to a layer in a chip. The dimension in which these vias primarily extend is often referred to as a “vertical” dimension with respect to the plane of the circuitry layer. Some vias, for example, are used to enable signals to travel between two circuitry layers in a microprocessor or between a bit line and a word line in a memory chip. These vias may sometimes be referred to as standard via interconnects. Standard via interconnects are typically used in middle-of-the-line layers and back-end-of-the-line layers. Standard via interconnects are often relatively similar in size to the node size in the design in which they are installed. A standard via interconnect may be 10 nm to 50 nm wide, for example, and 20 nm to 100 nm deep.

Some vias, however, are designed to be significantly larger than a standard via interconnect. These vias are often referred to herein as “deep vias.” These deep vias often span a vertical distance through a large amount of a dielectric material (e.g., silicon). Like standard via interconnects, these deep vias may often be used to connect two circuitry layers, but rather than connecting adjacent or near-adjacent layers, these deep vias may be used to connect layers at two sections of a chip that are 100,000 nm (100 microns) apart. Some deep vias may also be used to connect a circuitry layer to an interconnect layer, such as a series of solder balls in a ball-grid array. Rather than approximately 10 nm wide, these deep vias may be 10,000 nm (10 microns) wide or wider.

Like a standard via interconnect, deep vias are typically filled with conductive material such as copper, tungsten, cobalt, and ruthenium. This results in an extremely large amount of conductive material as compared to the size of the typical wires, transistors, and standard via interconnects that may be found in the circuitry layers near these deep vias. This relatively large mass of conductive material in a typical deep via can, in certain circumstances, cause high levels of mechanical stress to the nearby structures in a chip.

For example, the conductive material within a deep via can heat and cool during use of the device into which the deep via is installed. As the conductive material heats and cools, it expands and contracts. Because of the relatively large mass of the conductive material, this expansion and contraction can result in a similarly relatively large application of force upon the relatively small structures towards which and away from which the conductive material is expanding and contracting. Put another way, a thermal expansion may result in a small percentage increase in the width of a deep via that is normally 15,000 nm (15 microns) wide. However, a small percentage increase in a 15,000 nm wide deep via may have disproportionately large effects on a nearby structure that is only 10 nm wide. These effects may include a mechanical force being applied to the structure and components around the structure shifting position.

As a result, structures near deep vias may be particularly sensitive to the operating temperature of the device (e.g., memory chip) or the operating temperature of the deep via itself. This may cause device instability, including circuits performing inconsistently or becoming non-functional when the temperature at a deep via reaches (or cools to) a certain level. In some instances, this instability may be eliminated when the temperature at the deep via returns to normal levels. However, in some instances the mechanical stress caused by the deep via expansion may result in permanent damage to nearby structures.

One method of addressing the stress caused by thermal expansion and contraction is to design a keep-out zone around deep vias. These keep-out zones may reserve a relatively large amount of space surrounding a deep via for stress absorption. Designs with these keep-out zones typically do not allow smaller structures to be placed in the keep-out zone.

However, in order to increase their chances of efficacy, these keep-out zones are typically also relatively large. For example, a keep-out zone of a deep via with a 15,000 nm (15 microns) diameter may surround the deep via with 5,000 nm (5 microns) of reserved space. This would result in a circular area with a 25,000 nm (25 microns) diameter in which devices cannot be formed. In a design in which the node size may be 10 nm, an area of 25,000 nm in which devices cannot be formed would represent a significant amount of space.

To address some of the above problems, some embodiments of the present disclosure include a deep via with a stress-absorbing void embedded within the conductive material. This void may be located within the horizontal center of the conductive material, and may be filled, for example, with air, another gas, a vacuum or a near vacuum.

Some embodiments of the present disclosure may form a via with a stress-absorbing void with two sections. A first, wider section may contain the stress-absorbing void. A second, narrower section may be sealed during formation, encapsulating the void within the first section. For example, filling a deep via trench with the described first and second section with a conformal application of a conductive material from the second-narrower section of the trench may cause the narrower section of the trench to seal before the wider section of the trench is filled with conductive material. This incomplete filling of the wider section may result in a stress-absorbing void to remain within the wider section.

The conductive material within a deep via that contains a stress-absorbing void may still expand and contract when heated and cooled. However, the conductive material may be capable of expanding into the void within the via rather than outward toward the surrounding structures. This inward expansion may reduce the extent to which the conductive material expands into and exerts force on smaller, surrounding structures of the device. This, in turn, may reduce the necessary size of keep-out zones near deep vias, or eliminate the need for keep-out zones entirely.

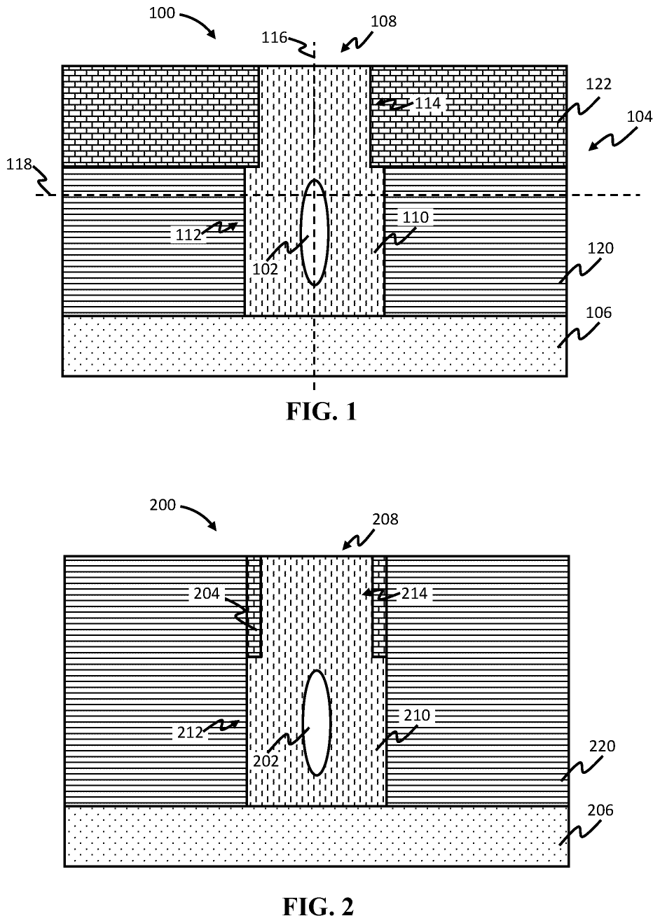

FIG. 1, for example, discloses a deep-via structure 100 with stress-relief void 102 within deep via 108 and bi-layer dielectric 104. Deep-via structure 100 is formed upon substrate 106, which may contain, for example, chip circuitry (e.g., front-end-of-the-line devices), inter-layer contacts (e.g., middle-of-the-line contacts), or inter-chip connections (e.g., back-end-of-the-line dielectic and wiring, connection to a land-grid array). Deep-via structure 100 may be, for example an interposer. Deep via 108 may, for example, be integrated into a microprocessor chip and connect to one or more layers of the microprocessor chip. For example, deep via 108 may be formed as a “via-first” through-silicon via, and may thus be integrated into a substrate of the microprocessor chip and connect to a front-end-of-the-line (“FEOL”) layer of the chip. Deep via 108 may also be formed as a “via-middle” through-silicon via, and may thus pass through a substrate of the microprocessor chip, and potentially the FEOL layer of the microprocessor chip, and connect to a metal layer in a back-end-of-the-line (“BEOL”) layer of the chip (i.e., at or near the connection between the FEOL layer and the BEOL layer). Deep via 108 may also be formed as a “via-last” through-silicon via, and may thus span the depth of a substrate, FEOL layer, and BEOL layer of the microprocessor chip and connect to the back side of the BEOL layer of the chip (i.e., at or near the end of the BEOL layer that is opposite to the connection between the FEOL layer and the BEOL layer).

In some embodiments, deep via 108 may act as an interposer between two microprocessor chips. For example, deep via 108 may connect a first microprocessor chip to a second microprocessor chip. This may include for example, one end of deep via 108 connecting to the FEOL layer of the first microprocessor chip. Deep via 108 may then pass through a substrate and connect to the BEOL layer of a second microprocessor chip.

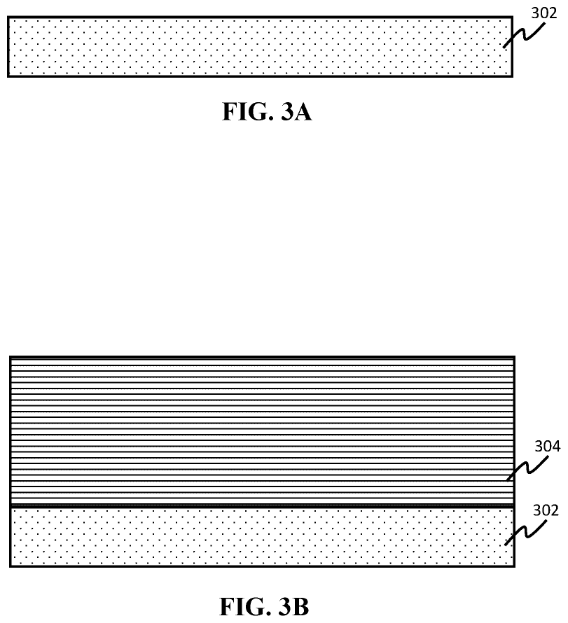

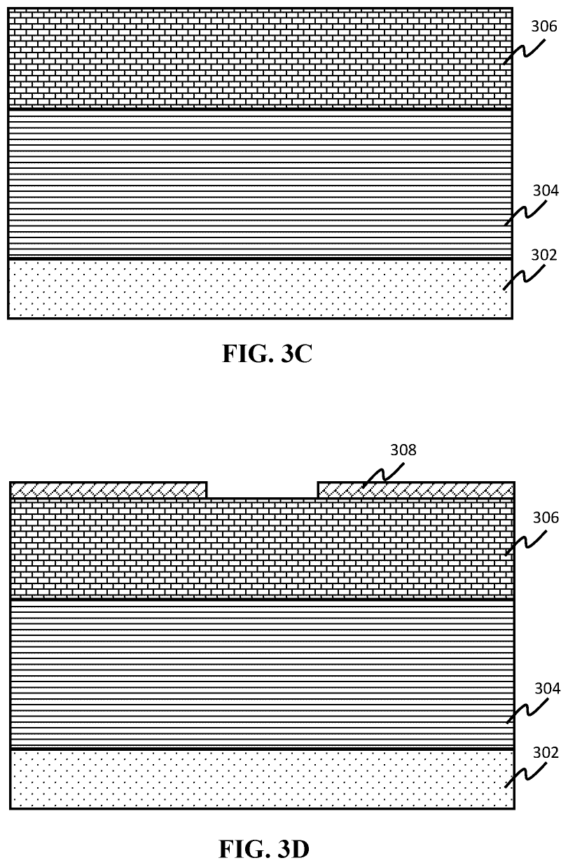

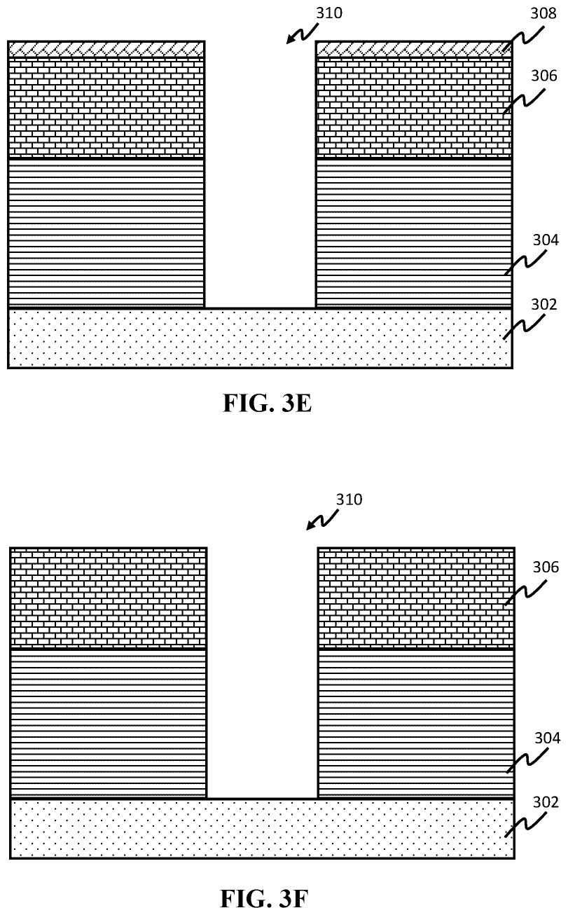

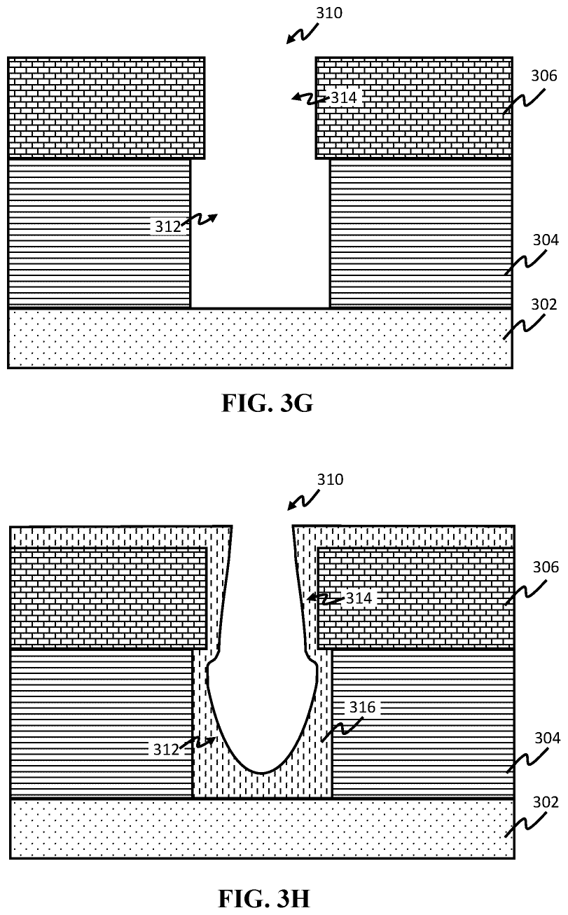

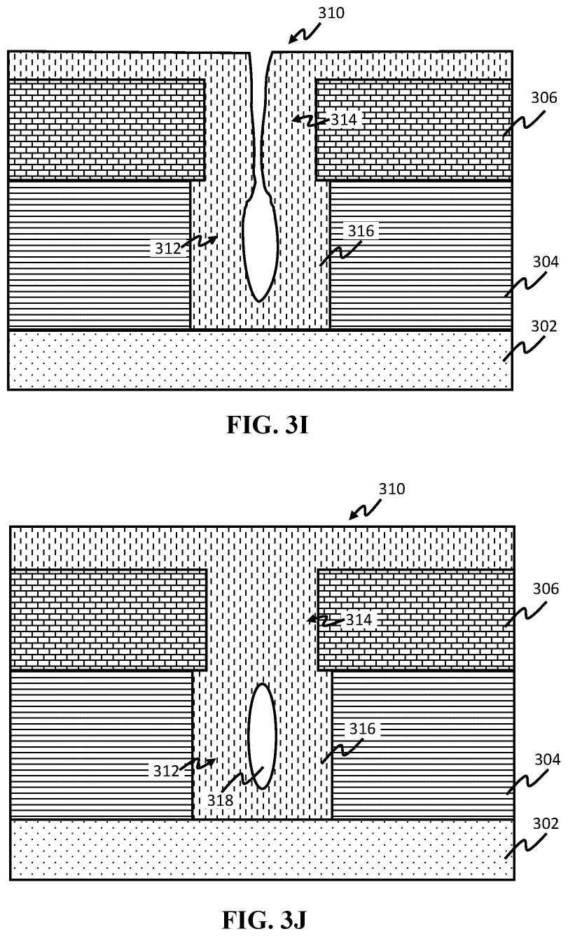

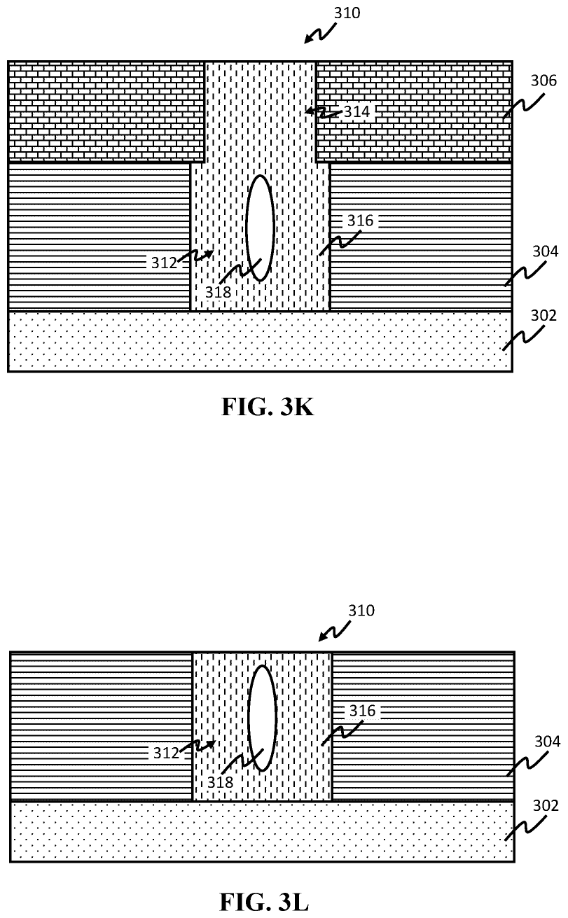

Deep-via structure 100 contains deep via 108, which is filled with stress-relief void 102 and conductive material 110. Conductive material 110 may include, for example, copper or tungsten. Stress-relief void 102, on the other hand, is characterized as a space within conductive material 110. For example, stress-relief void 102 could take the form of an air space trapped within the tungsten of conductive material 110. The precise composition of stress-relief void may depend on the environment in which conductive material 110 was applied within deep via 108. If conductive material was applied in a vacuum, stress-relief void 102 could be a vacuum. In theory, stress-relief void could also be a non-air gas or a liquid. The formation of a stress-relief void is detailed, for example, in FIGS. 3G-3L.

Deep via 108 is illustrated as containing a first section 112, second section 114, major dimension 116, and minor dimension 118. “Major dimension,” as used herein, refers to the larger dimension of a structural element, whereas “minor dimension,” as used herein, refers to the smaller dimension of a structural element. In this example, deep via 108 is illustrated as taller than it is wide, and thus the height of deep via 108 is referred to as major dimension 116. Thus, the width of deep via 108 is, as illustrated, considered to be perpendicular to major dimension 116.

As illustrated, therefore, deep via 108 has two widths that are perpendicular to major dimension 116. First section 112 has a first width that is perpendicular to major dimension 116, and second section 114 has a second width that is perpendicular to major dimension 116. The width of first section 112 is greater than the width of second section 114.

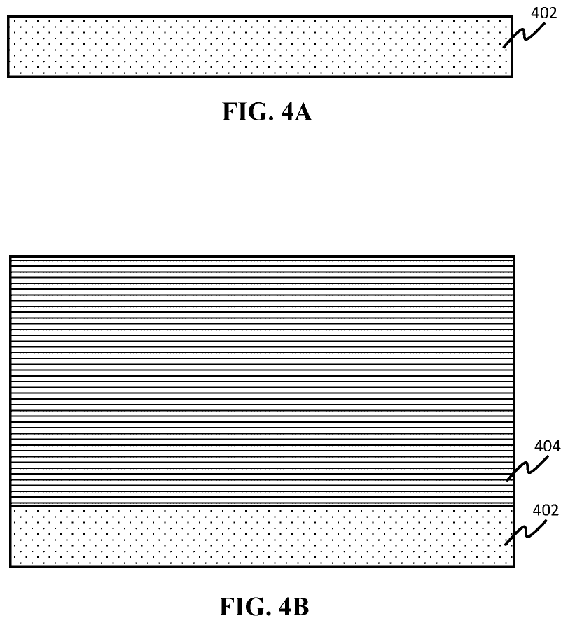

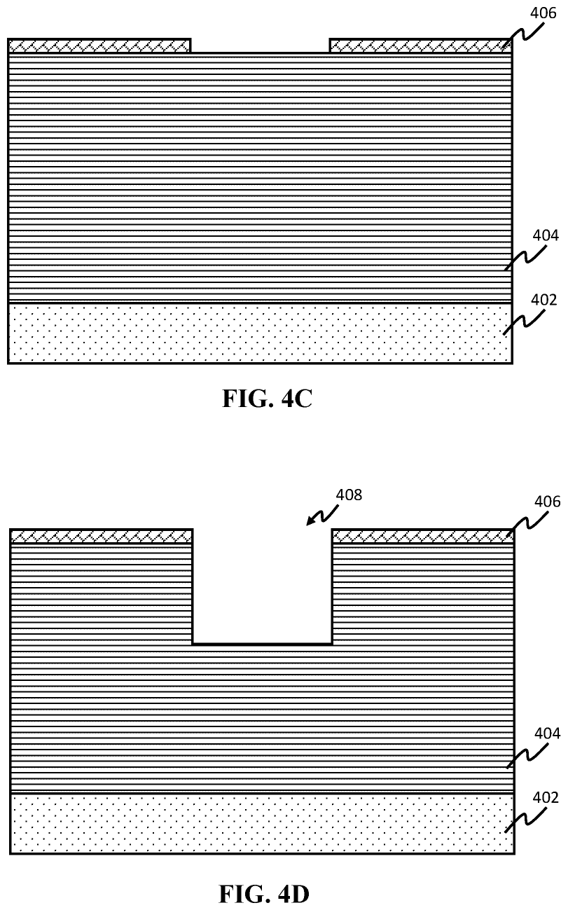

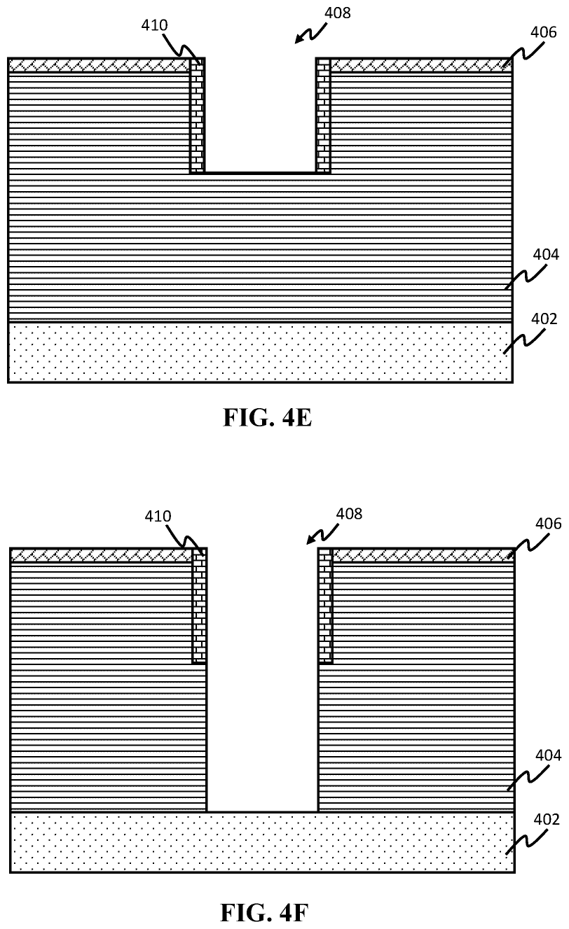

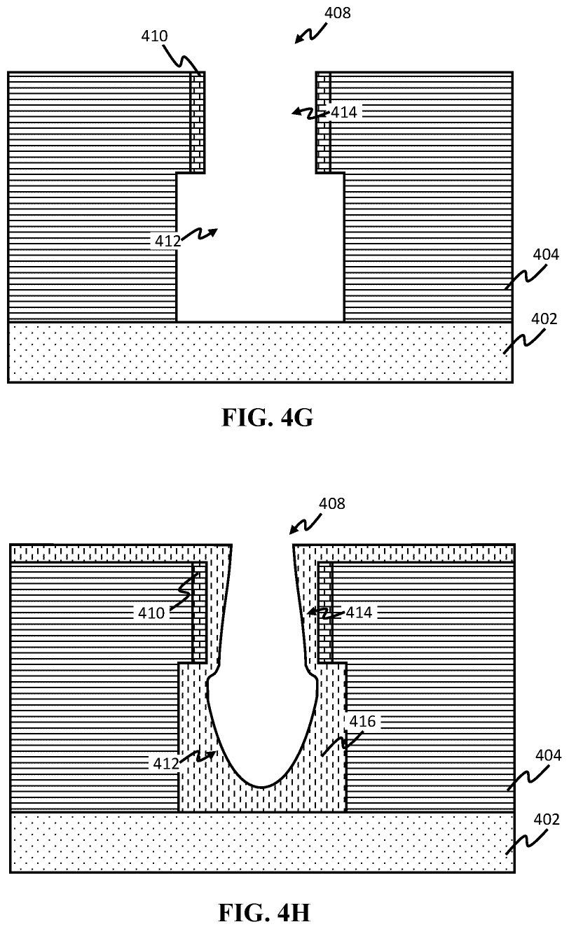

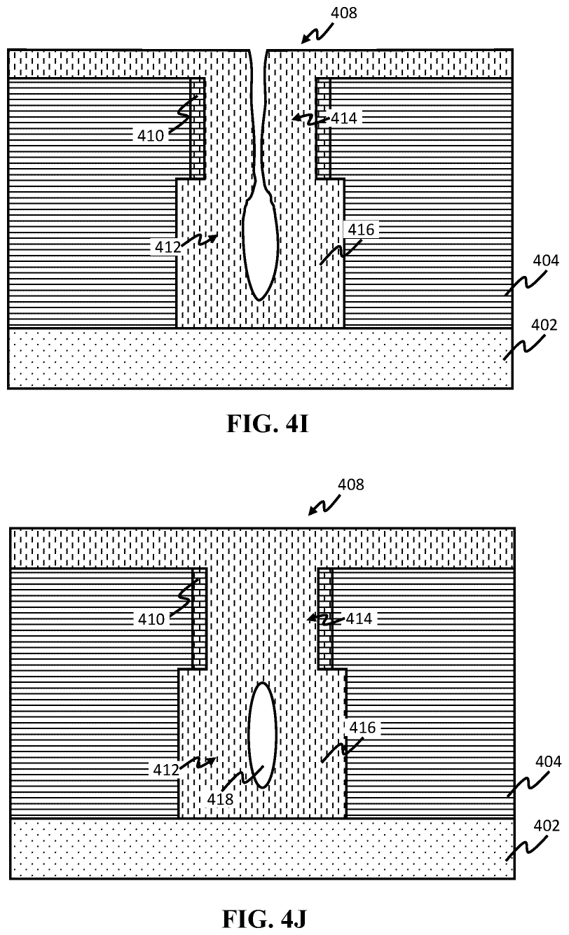

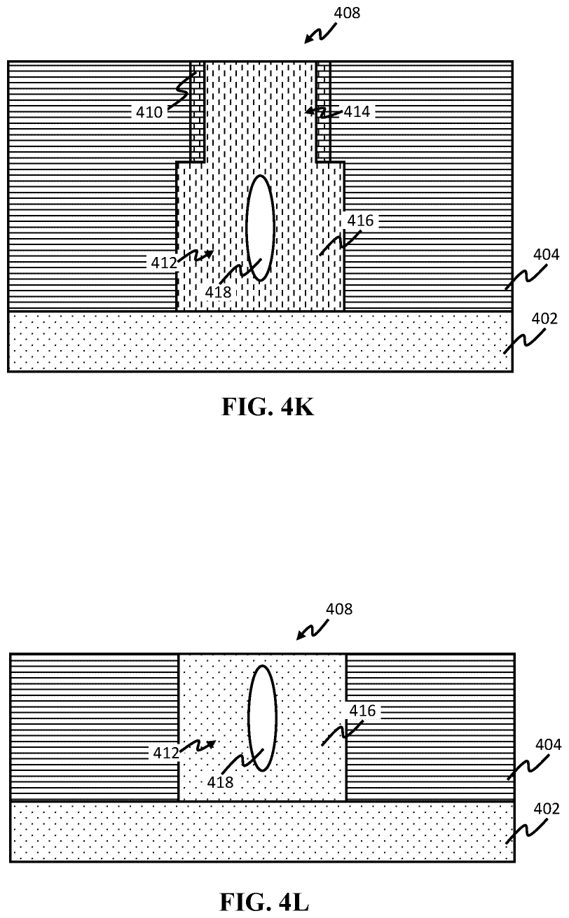

Bi-layer dielectric 104 contains a first dielectric 120 and second dielectric 122 that is formed upon first dielectric 120. Because they both at least partially surround and touch conductive material 110 in deep via 108, both first dielectric 120 and second dielectric 122 may be referred to herein as via-interfacing layers. First dielectric 120 is formed upon substrate 106, and may take the form of a dielectric with a low relative dielectric constant, such as silicon dioxide. Second dielectric 122 may be a dielectric that exhibits etch selectivity to first dielectric 120 (i.e., that is resistant to an etchant that can be used to selectively etch first dielectric 120). This selective etching is discussed with respect to FIGS. 3A-3L and 4A-4L. If first dielectric 120 is silicon dioxide, for example, second dielectric 122 may be silicon nitride.

As illustrated, conductive material 110 interfaces with first dielectric 120 within first section 112 and interfaces with second dielectric 122 within second section 114. As illustrated, stress-relief void 102 is embedded within conductive material 110 within first section 112. However, in some embodiments, stress-relief void 102 may span into second section 114.

Deep-via structure 100 has been described above as containing a bi-layer dielectric (i.e., first dielectric 120 and second dielectric 122). In such embodiments, deep-via structure 100 may be, for example, an interposer. However, in some embodiments deep-via structure may take the form of a through-silicon via. In such embodiments, the overall structure of deep-via structure 100 that is illustrated in FIG. 1 may remain essentially the same, but the nature of specific components may differ. For example, in some embodiments the first via interfacing layer (i.e., first dielectric 120) may actually take the form of a silicon layer. For this reason, first dielectric 120 or the alternative silicon layer could both generically be referred to as a via-interfacing layer, because they at least partially surround the conductive material 110 that forms most of deep via 108.

In a through-silicon via, substrate 106 may take the form of a connection layer into which devices that the through-silicon via connects are embedded. In these embodiments, second dielectric 122 may remain a dielectric and may still be used to selectively etch the width of the silicon layer in first section 112. However, in these embodiments, second dielectric 122 may be the only dielectric in deep-via structure 100.

Of note, deep-via structure 100 can be described as having a thickness that is parallel to the major dimension 116 of deep via 108. In other words, the thickness of deep-via structure 100 could be described as the distance between the top of substrate 106 and the top of second dielectric 122 or the top of conductive material 110. In other words, major dimension 116 of deep via 108, as illustrated, spans the thickness of deep-via structure 110.

Also of note, the illustration of FIG. 1, as well as the illustrations presented in FIGS. 2-4L, are intended to serve as abstract depictions for the purpose of understanding. For this reason, the relative sizes and shapes of the components of deep-via structure 100, for example, are not intended to be precise representations of the real-life sizes and shapes of deep-via structure 100 when physically reduced to practice.

For example, while FIG. 1 illustrates second dielectric 122 as approximately half as thick as first dielectric 120, in practice second dielectric 122 may actually be significantly thinner than first dielectric 120. In some embodiments, the thickness of second dielectric 122 may account for 10% of the total thickness of via 310. In theory, second dielectric 122 may also actually be removed from deep-via structure 100 before device operation.

Similarly, the size and shape of stress-relief void 102 may vary based on the proportions of the remaining components of deep-via structure 100 as well as conditions under which conductive material 110 is applied within deep via 108. For example, if first section 112 of deep via 108 is relatively thick (i.e., long in a dimension parallel to major dimension 116) as compared to the width of deep via 108 at first section 112 and second section 114, stress-relief void will also be relatively thick (i.e., long in a dimension parallel to major dimension 116). As the width of deep via 108 at first section 112 increases as compared to the width of deep via 108 at second section 114, the width of stress-relief void 102 is likely to increase. However, as the widths of deep via 108 at first section 112 and deep via 108 at second section 114 increase with respect to the overall thickness of deep via 108, the thickness of stress-relief void 102 is likely to decrease. In some embodiments, the resistance of deep via 108 may be negatively impacted if the volume of stress-relief void 102 is too large or if stress-relief void 102 is too wide as compared to the width of deep via 108. Thus, in some embodiments it may be beneficial to limit the volume and width of stress-relief void 102. In some embodiments, therefore, the total volume of stress relief void 102 may be less than 10% of the total volume of deep via 108.

FIG. 2 discloses a deep-via structure 200 with a stress-relief void 202 and a spacer element 204. Similar to deep-via structure 100, deep-via structure 200 is formed upon a substrate (substrate 206) and contains deep via 208 that is filled with conductive material 210 and stress-relief void 202. Deep via 208 also has two sections: first section 212 and a narrower second section 214.

Deep-via structure 200 also includes dielectric 220, which, as illustrated, spans the entire thickness of deep-via structure 200. Within deep via 208, conductive material 210 interfaces with dielectric 220 within first section 212 and interfaces with spacer element 204 within second section 214. In other words, spacer element 204 takes the form of as a spacer between conductive material 210 and dielectric 220 within second section 214. Similar to dielectric 122, spacer element 204 may be a dielectric that is resistant to an etchant that can be used to selectively etch dielectric 220. In some embodiments, spacer element 204 may slow be a non-dielectric material, such as a conductive material. This may reduce the overall resistance of deep via 208. The formation of a spacer element, such as spacer element 204, within a deep-via structure is illustrated in FIGS. 4D-4F.

Similar to FIG. 1, the precise composition, size, and shape of stress-relief void 202 may vary based on the relative sizes and shapes of sections 212 and 214 of deep via 208.

Similar to deep-via structure 100, deep-via structure 200 may also take the form of a through-silicon via. In these embodiments, dielectric 220 may take the form of a silicon layer, while spacer element 204 may still be a conductive material or a dielectric and may still be used to selectively etch the silicon in via 208 at section 212.

FIGS. 3A-3L provide example stages of forming a deep via with a stress-relief void in a bi-layer dielectric. While these stages do provide an example process of forming a deep via such as deep via 108 within deep-via structure 100, these stages are not intended to be presented as the only possible or the most optimal stages of forming such a deep via or stress-relief void.

FIG. 3A discloses a first stage of forming a deep via with a stress-relief void in a bi-layer dielectric. At this stage, only substrate 302 is present. Substrate 302 may contain, for example, chip circuitry (e.g., front-end-of-the-line devices), inter-layer contacts (e.g., middle-of-the-line contacts), or inter-chip connections (e.g., back-end-of-the-line dielectic and wiring, connection to a land-grid array).

FIG. 3B discloses a second stage of forming a deep via with a stress-relief void in a bi-layer dielectric. At this stage, a first dielectric 304 has been formed upon substrate 302. First dielectric 304 may be designed to span the majority of the thickness of the eventual deep via, and may thus be formed as a relatively thick layer. First dielectric 304 may be SiO₂ or another low-k dielectric.

FIG. 3C discloses a third stage of forming a deep via with a stress-relief void with a stress-relief void in a bi-layer dielectric. At this stage, a second dielectric 306 is formed upon first dielectric 304. Second dielectric 306 may be chosen from a variety of dielectrics with etching sensitivities that differ from the etching sensitivities of first dielectric 304. For example, if first dielectric 304 is composed of SiO₂, second dielectric may be composed of SiN.

FIG. 3D discloses a fourth stage of forming a deep via with a stress-relief void in a bi-layer dielectric. At this stage, via mask 308 is patterned onto second dielectric 306. Via mask 308 may be selected based on its resistance to a directional etching that may be used to etch a via into first dielectric 304 and second dielectric 306. For example, if first dielectric 304 is composed of SiO₂ and second dielectric is composed of SiN, via mask 308 may be composed of a metal nitride such as titanium nitride or tantalum nitride.

FIG. 3E discloses a fifth stage of forming a deep via with a stress-relief void in a bi-layer dielectric. At this stage, deep via 310 has been etched into first dielectric 304 and second dielectric 306. Deep via 310 may be etched, for example, using anisotropic etching such as reactive ion etching. FIG. 3F discloses a sixth stage of forming a deep via with a stress-relief void in a bi-layer dielectric. At this stage, via mask 308 is no longer needed and has been removed.

FIG. 3G discloses a seventh stage of forming a deep via with a stress-relief void in a bi-layer dielectric. At this stage, first dielectric 304 has been isotropically etched with an etchant to which second dielectric 306 is not sensitive. This results in two sections of deep via 310: first section 312 and second section 314. Because first section 312 occupies the portion of deep via 310 that is surfaced by first dielectric 304, it has been etched and is wider than second section 314 as a result.

FIG. 3H discloses an eighth stage of forming a deep via with a stress-relief void in a bi-layer dielectric. At this stage, conductive material 316 has been partially applied into via 310 through conformal deposition. Conductive material 316 may be, for example, copper or tungsten. As can be seen, due to the different thicknesses of via 310 at first section 312 and second section 314, the deposition pattern of conductive material 316 differs slightly between the two sections.

FIG. 3I discloses a ninth stage of forming a deep via with a stress-relief void in a bi-layer dielectric. At this stage, conductive material 316 has been more completely applied into via 310 through continued conformal deposition. Again, due to the different thicknesses of via 310 at first section 312 and second section 314, conductive material 316 has almost sealed via 310 in second section 314 while a larger void remains within first section 312.

FIG. 3J discloses a tenth stage of forming a deep via with a stress-relief void in a bi-layer dielectric. At this stage, the conformal deposition of conductive material 316 has sealed second section 314 of via 310 before first section 312 of via 310 was filled. This has resulted in stress-relief void 318. Stress-relief void 318 may be useful, for example, in absorbing mechanical stress that results from thermal expansion and contraction of conductive material 316 in via 310 during operation.

Of note, the conformal deposition of conductive material 316 within via 310 has also caused deposition of conductive material on top of second dielectric 306. This excess conductive material can be etched in a planarization process after sealing second section 314.

FIG. 3K illustrates the result of a planarization step in which the excess conductive material 316 has been etched to the top of section 314 and second dielectric 306. This is effectively the state illustrated by deep via structure 100 in FIG. 1. This may be performed, for example, by performing chemical mechanical polishing (CMP) on conductive material 316 using a chemical slurry that does not readily corrode second dielectric 306. This would effectively utilize second dielectric 306 as an etch stop.

Of further note, there may also be benefit to reduce the depth of deep-via structure 300 by removing conductive material 316 within second section 314 and removing second dielectric 306. Thus, some embodiments may perform a planarization step in which deep via structure 300 is polished with a CMP chemical that strongly corrodes second dielectric 306 and conductive material 316, but does not corrode first dielectric 304.

FIG. 3L illustrates the result of such a planarization step. In some embodiments, the stages illustrated in FIGS. 3K and 3L may be part of a single planarization process. In other embodiments, the stage illustrated in FIG. 3K may result from a first planarization process (for example, with a first CMP chemical) and the stage illustrated in FIG. 3L may result from a second planarization process (for example, with a second CMP chemical).

Etching away deep via structure 300 to the top of first dielectric 305, as illustrated in FIG. 3L, may be considered an optional step in FIGS. 3A-3L. In some use cases the reduction of depth of the deep via structure may be worth the added process complexity. In other use cases, however, the reduction of the depth may not result in significant enough benefits to make the more substantial etching worth performing. In these use cases, deep-via structure 300 may be finalized as illustrated in FIG. 3K.

FIGS. 4A-4J provide example stages of forming a deep via with a stress-relief void and a spacer dielectric. While these stages do provide an example process of forming a deep via such as deep via 208 within deep-via structure 200, these stages are not intended to be presented as the only possible or the most optimal stages of forming such a deep via or stress-relief void.

FIG. 4A discloses a first stage of forming a deep via with a stress-relief void and a spacer dielectric. At this stage, only substrate 402 is present. FIG. 4B discloses a second stage of forming a deep via with a stress-relief void and a spacer dielectric. At this stage, a first dielectric 404 has been formed upon substrate 402. First dielectric 404 may be designed to span the entire thickness of the eventual deep via, and may thus be formed as a thick layer.

FIG. 4C discloses a third stage of forming a deep via with a stress-relief void and a spacer dielectric. At this stage, via mask 406 onto first dielectric 404. Via mask 406 may be selected based on its resistance to a directional etching that may be used to etch a via into first dielectric 404.

FIG. 4D discloses a fourth stage of forming a deep via with a stress-relief void and a spacer dielectric. At this stage, a first directional-etch process has been performed upon first dielectric 404, resulting in the beginning of deep via 408. In some embodiments, this etching may have been performed to a precise, pre-determined depth that is designed to correspond to the pre-determined depth of a narrow section of a via (similar to second sections 114 and 214).

FIG. 4E discloses a fifth stage of forming a deep via with a stress-relief void and a spacer dielectric. At this stage, a dielectric spacer 410 has been applied to the inner walls of the beginning of deep via 408. In some embodiments, dielectric spacer 410 may have been applied through conformal deposition (e.g., atomic layer deposition, chemical vapor deposition, plasma enhanced chemical vapor deposition). In some embodiments, dielectric spacer 410 may have been etched to the shape shown in FIG. 4E using directional anisotropic etch (e.g., reactive ion etching).

FIG. 4F discloses a sixth stage of forming a deep via with a stress-relief void and a spacer dielectric. At this stage, a second directional-etch process has been performed upon first dielectric 404, resulting in the entire trench of deep via 408 being formed. Of note, spacer dielectric 410 and via mask 406 are not illustrated as being etched by this second directional-etch process because, in typical embodiments, they would both exhibit etch selectivity to first dielectric 404. In practice, the top surfaces of both via mask 406 and spacer dielectric via mask 406 may be slightly eroded from this etch process. However, in typical embodiments, via mask 406 and spacer dielectric 410 may have been deposited thick enough past the top of first dielectric 404 that they are able to sustain that slight erosion. This partial erosion would, in most embodiments, become irrelevant when deep-via structure 400 is planarized during the removal of via mask 406 (and the corresponding top portion of spacer dielectric 410).

FIG. 4G discloses a seventh stage of forming a deep via with a stress-relief void and a spacer dielectric. At this stage, via mask 406 and the corresponding top portion of dielectric spacer 410 have been removed. Further, first dielectric 404 has been isotropically etched with an etchant to which dielectric spacer 410 is not sensitive. This results in two sections of deep via 408: first section 412 and second section 414. Because first section 412 occupies the portion of deep via 408 that is surfaced by first dielectric 404, it has been etched and is wider than second section 414 as a result.

FIG. 4H discloses an eighth stage of forming a deep via with a stress-relief void and a spacer dielectric. At this stage, conductive material 416 has been partially applied into via 408 through conformal deposition. As can be seen, due to the different thicknesses of via 408 at first section 412 and second section 414, the deposition pattern of conductive material 416 differs slightly between the two sections.

FIG. 4I discloses a ninth stage of forming a deep via with a stress-relief void and a spacer dielectric. At this stage, conductive material 416 has been more completely applied into via 408 through continued conformal deposition. Again, due to the different thicknesses of via 408 at first section 412 and second section 414, conductive material 416 has almost sealed via 408 in second section 414 while a larger void remains within first section 412.

FIG. 4J discloses a tenth stage of forming a deep via with a stress-relief void and a spacer dielectric. At this stage, the conformal deposition of conductive material 416 has sealed second section 414 of via 408 before first section 412 of via 408 was filled. This has resulted in stress-relief void 418. Stress-relief void 418 may be useful, for example, in absorbing mechanical stress that results from thermal expansion and contraction of conductive material 416 in via 408 during operation.

Of note, the conformal deposition of conductive material 416 within via 408 has also caused deposition of conductive material on top of first dielectric 404 and spacer dielectric 410. This excess conductive material can be etched in a planarization process after sealing second section 414.

FIG. 4K illustrates the result of a planarization step in which the excess conductive material 416 has been polished using CMP to the top of second section 414, and first dielectric 404, and spacer dielectric 410. This is effectively the state illustrated by deep via structure 200 in FIG. 2. This may be performed, for example, by polishing conductive material 416 using an chemical that does not readily corrode first dielectric 404, spacer dielectric 410, or both. This would effectively utilize one or both of first dielectric 404 and spacer dielectric 410 as an etch stop.

Of further note, there may also be benefit to reduce the depth of deep-via structure 400 by removing second section 414 of the deep via and the corresponding portions of first dielectric 404 and spacer dielectric 410. Thus, some embodiments may perform a planarization step in which deep via structure 400 is etched with an chemical that corrodes all of conductive material 416, first dielectric 404, and spacer dielectric 410.

FIG. 4L illustrates the result of such a planarization step. Unlike the planarization step that was performed to create the result illustrated in FIG. 4K, it may not be feasible to use an etch stop to signal the completion of the desired etching of this planarization step. This is because all three components of deep via structure 400 above substrate 402 are being etched. However, it may be particularly important to avoid unwanted polishing into first section 412, because polishing section 412 may open stress-relief void 418, which may then be filled in later bonding or deposition steps. For this reason, this planarization step may be closely timed, rather than monitored for indications of hitting an etch-stop layer.

In some embodiments, the stages illustrated in FIGS. 4K and 4L may be part of a single planarization process. In other embodiments, the stage illustrated in FIG. 4K may result from a first planarization process (for example, with a first chemical that does not readily corrode first dielectric 404 and spacer dielectric 410) and the stage illustrated in FIG. 4L may result from a second planarization process (for example, with a second chemical that does readily corrode first dielectric 404 and spacer dielectric 410). While performing these two planarization steps separately may add process complication, it may also beneficially enable more accurate control of the second planarization step. Specifically, the first planarization step may cause deep-via structure 400 to have a very flat top surface with a known starting point (e.g., the top of first dielectric 404). Beginning the second, timed planarization step from this known, precise starting point may therefore cause the timed control of the second planarization step to have more accurate and predictable results.

Similar to the result discussed in FIG. 3L, polishing away deep via structure 400 to the top of first section 412, as illustrated in FIG. 4L, may be considered an optional step in FIGS. 4A-4L. In some use cases the reduction of depth of the deep via structure may be worth the added process complexity. In other use cases, however, the reduction of the depth may not result in significant enough benefits to make the more substantial etching worth performing. In these use cases, deep-via structure 400 may be finalized as illustrated in FIG. 4K.

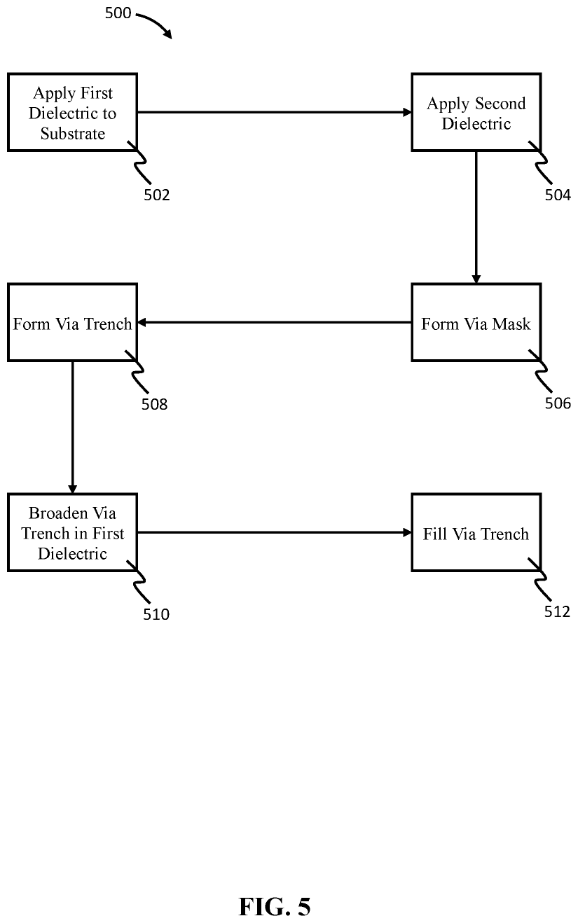

FIG. 5 discloses a process 500 of forming a deep via with a stress-relief void. Process 500 is presented as a general process for the sake of understanding, and is intended to apply to various methods of forming a deep via with a stress-relief void in practice. For example, process 500 could be performed in a way that resulted in deep-via structure 100, deep-via structure 200, stages 2-10 of FIGS. 3B-3J, or stages 3-10 of FIGS. 4B-4J.

Process 500 begins in block 502 in which a first dielectric is applied to a substrate. This substrate may contain, for example, chip circuitry (e.g., front-end-of-the-line devices), inter-layer contacts (e.g., middle-of-the-line contacts), or inter-chip connections (e.g., back-end-of-the-line dielectic and wiring, connection to a land-grid array). Of note, in embodiments in which a deep-via structure is being provided for a through-silicon via, this step may be replaced with applying a silicon layer to the substrate.

Process 500 continues in block 504 in which a second dielectric is applied to the structure. In some embodiments, this second dielectric could be formed upon the first dielectric, forming a bi-layer dielectric. This may resemble the stage illustrated in FIG. 3C. In some embodiments, this second dielectric could be applied through conformal deposition as a spacer element in a preliminary via. In these embodiments, block 504 may follow a masking and preliminary directional etching process to form this preliminary via, and may resemble the stage illustrated in FIG. 4E.

Process 500 also includes forming a via mask in block 506. In some embodiments, this via mask could be applied on top of a bi-layer dielectric formed in block 504, in which case block 506 would follow block 504 and may resemble the stage illustrated in FIG. 3D. In some embodiments, this via mask could be applied on top of the first dielectric that was applied in block 502, in which case block 506 may be performed prior to block 504. This may resemble the stage illustrated in FIG. 4C.

Process 500 continues in block 508 in which a via trench is formed through a directional etching process (e.g., nisotropic etching). In some embodiments, block 508 may form a complete via through a bi-layer dielectric. This may resemble the stage illustrated in FIG. 3E. In some embodiments, block 508 may be a second stage of etching and may complete a via from a previously formed preliminary via. This may resemble the stage illustrated in FIG. 4F.

Process 500 continues in block 510 in which the via trench is broadened into the first dielectric. This may be performed through an isotropic etching process that introduces an etchant to which the first dielectric is sensitive but the second dielectric is not sensitive. This may result in a first section of the via trench (i.e., the section that is surrounded by the first dielectric) that is wider than a second section of the via trench (i.e., the section that is surrounded by the second dielectric). This may resemble the stages illustrated in FIGS. 3G and 4G.

Process 500 continues in block 512 in which the via trench is filled with a conductive material using a conformal deposition process. Due to the broadening of the first via section in block 510, this may result in a stress-relief void within the conductive material within the first via section. In some embodiments, this stress-relief void may also partially extend into the second via section.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A deep-via structure, the deep-via structure comprising:
a via-interfacing layer;
a via that is embedded within the via-interfacing layer, wherein the via comprises a conductive material; and
a stress-relief void formed within the via.

2. The deep-via structure of claim 1, wherein the via comprises:
a major dimension that spans the thickness of the deep-via structure;
a first section of the via, wherein the first section is of a first width that is perpendicular to the major dimension; and
a second section of the via, wherein the second section is of a second width that is perpendicular to the major dimension and wherein the second width is smaller than the first width.

3. The deep-via structure of claim 2, wherein the via-interfacing layer is a first via-interfacing layer, wherein the conductive material interfaces with the first via-interfacing layer in the first section, and wherein the conductive material interfaces with a second via-interfacing layer in the second section.

4. The deep-via structure of claim 3, wherein the second via-interfacing layer is a spacer element embedded within the first via-interfacing layer.

5. The deep-via structure of claim 3, wherein the spacer element is a second conductive material.

6. The deep-via structure of claim 3, wherein the first via-interfacing layer and second via-interfacing layer form a bi-layer dielectric.

7. The deep-via structure of claim 1, wherein the via-interfacing layer is a dielectric.

8. The deep-via structure of claim 1, wherein the via-interfacing layer is a silicon layer.

9. The deep-via structure of claim 1, wherein the via is integrated into a substrate of a microprocessor chip and connects to a front-end-of-the-line layer of the microprocessor chip.

10. The deep-via structure of claim 1, wherein the via passes through a substrate and a front-end-of-the-line layer of a microprocessor chip and connects to a metal layer in a back-end-of-the-line layer of the microprocessor chip.

11. The deep-via structure of claim 1, wherein the via connects to a back side of a back-end-of-the-line layer of a microprocessor chip.

12. A microprocessor chip comprising:
a first deep-via structure, wherein the first deep-via structure comprises:
a first via-interfacing layer;
a first via that is embedded within the first via-interfacing layer, wherein the first via comprises a first conductive material; and
a first stress-relief void formed within the first via; and
a second deep-via structure, wherein the second deep-via structure comprises:
a second via-interfacing layer;
a second via that is embedded within the second via-interfacing layer, wherein the second via comprises a second conductive material; and
a second stress-relief void formed within the second via.

13. The microprocessor chip of claim 12, wherein the first deep-via structure is integrated into a substrate in the chip and connects to a front-end-of-the-line layer of the microprocessor chip.

14. The microprocessor chip of claim 12, wherein one end of the second deep-via structure connects to a second microprocessor chip.

15. The microprocessor chip of claim 13, wherein the second deep-via structure connects to a back side of a back-end-of-the-line layer of a microprocessor chip.

16. The microprocessor chip of claim 13, wherein the first via comprises:
a major dimension that spans the thickness of the first deep-via structure;
a first section of the first via, wherein the first section is of a first width that is perpendicular to the major dimension; and
a second section of the first via, wherein the second section is of a second width that is perpendicular to the major dimension and wherein the second width is smaller than the first width.

17. The microprocessor chip of claim 16, wherein the first conductive material interfaces with the first via-interfacing layer in the first section, and wherein the first conductive material interfaces with a third via-interfacing layer in the second section.

18. The microprocessor chip of claim 17, wherein the third via-interfacing layer is a spacer element embedded within the first via-interfacing layer.

19. The microprocessor chip of claim 18, wherein the spacer element is a third conductive material.

20. The microprocessor chip of claim 17, wherein the first via-interfacing layer and third via-interfacing layer form a bi-layer dielectric.
